(19) United States
(12) Patent Application Publication
(10) Pub. No.: US 2006/0178019 A1
(43) Pub. Date: Aug. 10, 2006

(54) Low temperature deposition of silicon oxides and oxynitrides

(75) Inventors: Yoshihide Senzaki, Aptos, CA (US); Sang-In Lee, Cupertino, CA (US); Sang-Kyoo Lee, Seoul (KR)

Correspondence Address: DORSEY & WHITNEY LLP, 555 CALIFORNIA STREET, SUITE 1000, SUITE 1000, SAN FRANCISCO, CA, 94104, US

(73) Assignee: AVIZA TECHNOLOGY, INC., Scotts Valley, CA (US)

(21) Appl. No.: 10/524,980

(22) PCT Filed: Aug. 18, 2003
(86) PCT No.: PCT/US03/26083

§ 371 Date: Mar. 22, 2006

Related U.S. Application Data
(60) Provisional application No. 60/404,363, filed on Aug. 18, 2002.

(51) Int. Cl. H01L 21/31

(52) U.S. Cl. 438/788; 438/789

(57) ABSTRACT

The present invention relates to low temperature (i.e., less than about 450° C.) chemical vapor deposition (CVD) and low temperature atomic layer deposition (ALD) processes for forming silicon oxide and/or silicon oxynitride derived from silicon organic precursors and ozone. The processes of the invention provide good step coverage. The invention can be utilized to deposit both high-k and low-k dielectrics.

### CROSS-REFERENCE TO RELATED APPLICATIONS

This application is related to, and claims priority to, U.S. Provisional Patent Application No. 60/404,363, entitled Low Temperature Deposition of Silicon Oxides and Oxynitrides, filed Aug. 18, 2002.

### FIELD OF THE INVENTION

The present invention relates to the field of semiconductors. More specifically, the present invention relates to low temperature chemical vapor deposition (CVD) and low temperature atomic layer deposition (ALD) processes for forming silicon oxide and/or silicon oxynitride from silicon organic precursors and ozone.

### BACKGROUND OF THE INVENTION

CVD is a known deposition process. In CVD, two or more reactant gases are mixed together in a deposition chamber where the gases react in the gas phase and either deposit a film onto a substrate's surface or react directly on the substrate's surface. Deposition by CVD occurs for a specified length of time, based on the desired thickness of the deposited film. Since the specified time is a function of the flux of reactants into the chamber, the required time may vary from chamber to chamber.

ALD is also a known process. In a conventional ALD deposition cycle, each reactant gas is introduced sequentially into the chamber, so that no gas phase intermixing occurs. A monolayer of a first reactant (i.e., precursor) is physi- or chemisorbed onto the substrate's surface. Excessive first reactant is then evacuated, usually with the aid of an inert purge gas and/or pumping. A second reactant is then introduced to the deposition chamber and reacts with the first reactant to form a mono-layer of the desired film through a self-limiting surface reaction. The self-limiting reaction stops once the initially adsorbed first reactant fully reacts with the second reactant. Excessive second reactant is then evacuated with the aid of an inert purge gas and/or pumping. A desired film thickness is obtained by repeating the deposition cycle as necessary. The film thickness can be controlled to atomic layer (i.e., angstrom scale) accuracy by simply counting the number of deposition cycles.

It is known to use silicon oxide (SiOₓ) and silicon oxynitride (SiOₓN_{y}) films for gate and capacitor applications. However, present techniques, including present CVD techniques, for applying such films become less and less suitable as line width dimensions in integrated circuitry (IC) continue to scale down.

For example, it is known to use CVD to deposit the silicon oxide layers from a silicon organic precursor reacted with oxygen gas or water vapor. However, such CVD processes generally require temperatures above 600° C.—although bis(tertiary-butylamino)silane (BTBAS) and diethylsilane (Et₂SiH₂) react with oxygen gas (O₂) at 400° C. Such high temperatures result in oxidation of contact metals such as tungsten, thereby increasing line resistance. In addition, such high temperatures result in catalytic reaction of metals to form undesirable whiskers such as tungsten whiskers in the device structures. Thus, deposition processes that employ lower temperatures are needed.

In further example, in pre-metal dielectric (PMD) applications, it is known to use high-density plasma (HDP) CVD to deposit phosphorous doped glass (PSG) or nondoped silicate glass (NSG) at temperatures between 300 and 550° C. However, HDP CVD is limited in its gap-fill capability to an aspect ratio of approximately 3:1. Aspect ratio is the ratio of the trench height to its width; higher ratios are more difficult to fill. The presence of gaps, or voids, between metal features in a semiconductor device can lead to pockets of trapped water, micro-cracking and shorts. Thus, deposition processes that exhibit greater gap fill capabilities are needed.

### SUMMARY OF THE INVENTION

Low temperature (i.e., less than about 450° C.) deposition processes are provided for depositing silicon oxide and silicon oxynitride layers for spacer and pre-metal dielectric applications. The processes, which can be either CVD and ALD processes, use ozone as an oxidant in combination with silicon organic precursors and, optionally, a nitrogen source. The low temperature deposition processes provide good step coverage and gap-fill capability, providing a high aspect ratio of 6:1 or more.

In one aspect of the invention, a CVD process for depositing a silicon oxide layer on a substrate comprises at least one cycle comprising the following steps: (i) introducing a silicon organic precursor into a deposition zone where a substrate is located; and (ii) introducing ozone into the deposition zone. In this aspect of the invention, the steps can be performed simultaneously or sequentially. The precursor and the ozone react to form a layer of silicon oxide on the substrate.

In another aspect of the invention, a CVD process for depositing a silicon oxynitride layer on a substrate comprises at least one cycle comprising the following steps: (i) introducing a silicon organic precursor into a deposition zone where a substrate is located; (ii) introducing ozone into the deposition zone; and (iii) introducing a nitrogen source, such as ammonia (NH₃), into the deposition zone. Once again, the steps can be performed simultaneously or sequentially. The precursor, ozone and nitrogen source react to form a layer of silicon oxynitride on the substrate.

In still another aspect of the invention, an ALD process for depositing a silicon oxide layer on a substrate comprises at least one cycle comprising the following steps: (i) introducing a silicon organic precursor into a deposition zone where a substrate is located; (ii) purging the deposition zone; and (iii) introducing ozone into the deposition zone. In this aspect of the invention, the steps are performed sequentially. The cycle deposits one mono-layer of silicon oxide. The cycle can be repeated as many times as necessary to achieve the desired film thickness as long as each cycle is separated by an additional purging of the deposition zone.

In yet another aspect of the invention, an ALD process for depositing a silicon oxynitride layer on a substrate comprises at least one cycle comprising the following steps: (i) introducing a silicon organic precursor into a deposition zone where a substrate is located; (ii) purging the deposition zone; and (iii) introducing ozone and a nitrogen source, e.g., ammonia (NH₃), into the deposition zone. The steps are performed sequentially. The introduction of ozone and nitrogen can be done separately or simultaneously, in any order, and can optionally be separated by a step of purging the deposition chamber. The cycle deposits one mono-layer of silicon oxynitride. The cycle can repeated as many times as necessary to achieve the desired film thickness as long as each cycle is separated by an additional purging of the deposition zone.

Other aspects and advantages of the present invention will be apparent upon reading the following detailed description of the invention with reference to the attached drawings.

### BRIEF DESCRIPTION OF THE DRAWINGS

FIG. 1 illustrates and CVD process of the invention.

FIG. 2 illustrates an ALD process of the invention.

### DETAILED DESCRIPTION OF THE INVENTION

The present invention provides CVD and ALD methods of depositing silicon oxide and silicon oxynitride films on a substrate at low temperatures, i.e., below about 450° C., while simultaneously maintaining good step coverage characteristics. The methods of the invention utilize metal silicon organic precursors in combination with ozone. The deposition methods of the present invention can be used in depositing both high-k and low-k dielectrics.

The substrate to be coated can be any material with a metallic or hydrophilic surface which is stable at the processing temperatures employed. Suitable materials will be readily evident to those of ordinary skill in the art. Suitable substrates include silicon, ceramics, metals, plastics, glass and organic polymers. Preferred substrates include silicon, tungsten and aluminum. The substrate may be pretreated to instill, remove, or standardize the chemical makeup and/or properties of the substrate's surface. The choice of substrate is dependent on the specific application.

The silicon organic precursors include any molecule that can be volatilized and comprises, within its structure, one or more silicon atoms and one or more organic leaving groups or ligands that can be severed from the silicon atoms by a compound containing reactive oxygen (e.g., ozone) and/or reactive nitrogen (e.g., ammonia). Preferably, the silicon organic precursors consist only of one or more silicon atoms and one or more organic leaving groups that can be severed from the silicon atoms by a compound containing reactive oxygen and/or reactive nitrogen. More preferably, the silicon organic precursors are volatile liquids at or near room temperature, e.g., preferably within 100° C. and even more preferably within 50° C. of room temperature. Suitable silicon organic precursors will be evident to those skilled in the art. Preferred examples of suitable silicon organic precursors include, but are not limited to, tetramethyldisiloxane (TMDSO), hexamethyldisiloxane (HMDSO), hexamethyldisilazane (HMDSN), and silicon tetrakis(ethylmethyamide) (TEMASi), alkylaminosilane, alkylaminodisilane, alkylsilane, alkyloxysilane, alkylsilanol, and alkyloxysilanol. In one embodiment, the silicon precursors are aminosilane or silicon alkylamides. These compounds contain the Si-N bond which is quite labile and reacts readily with ozone at a low temperatures. The rate of precursor gas flow can range from 1 sccm to 1000 sccm. Preferably, the rate of precursor gas flow ranges from 10 to 500 sccm.

The ozone gas enables oxidation of the silicon organic precursors at lower temperatures than obtained using conventional oxidizers such as water (H₂O) or oxygen gas (O₂). Oxidation of the precursor with ozone gives good results at temperatures less than about 450° C. and as low as about 200° C. The temperature range is preferably from 300° C. to 400° C. Other advantages to the use of ozone instead of water include the elimination of hydroxyl bonds and the fixed/trapped charges caused by hydroxyl bonds and less carbon in the film. In a preferred embodiment only ozone is employed. In another preferred embodiment ozone is employed in admixture with oxygen. The ozone gas flow can be in the range from 10 to 2000 sccm. Preferably, the ozone gas flow ranges from 100 to 2000 sccm. Preferably, the concentration of ozone introduced into the deposition zone ranges 10 to 400 g/m³, more preferably from 150 to 300 g/m³. As a specific example, SiO₂ films with excellent step coverage with high aspect ratio trenches and uniformity were deposited using TEMASi and ozone at 400° C. at a pressure of 5 Torr. The precursor gas flow was about 30 sccm and the ozone concentration was 250 g/m³.

When the desired film is an oxynitride, a nitrogen source is additionally employed. The nitrogen source can be any compound that can be volatilized and contains, within its structure, a reactive nitrogen. Suitable nitrogen sources include, but are not limited to, atomic nitrogen, nitrogen gas, ammonia, hydrazine, alkylhydrazine, alkylamine and the like. Ammonia is preferred. The nitrogen source gas flows into the deposition chamber at a rate ranging from 10 to 2000 sccm. Preferably, the nitrogen source gas flows at a rate ranging from 100 to 2000 sccm.

In many embodiments, diluent gas is employed in combination with one or more of the reactant gases (e.g., precursor, ozone, nitrogen source) to improve uniformity. The diluent gas can be any non-reactive gas. Suitable diluent gases include nitrogen, helium, neon, argon, xenon gas. Nitrogen gas and argon gas are preferred for cost reasons. Diluent gas flows generally range from 1 sccm to 1000 sccm.

In some CVD embodiments, and every ALD embodiment, the introduction of one or more reactant gases into the deposition chamber is separated by a purge step. The purge can be performed by a low pressure or vaccum pump. Alternatively, the purge can be performed by pulsing an inert purge gas into the deposition chamber. Suitable purge cases include nitrogen, helium, neon, argon, xenon gas. Alternatively, a combination of pumping and purge gas can be employed.

In all cases the gas flows cited above depend on the size of the chamber and pumping capability, as the pressure must be within the required range. The process pressure required depends on the deposition method but is typically in the range 1 mTorr to 760 Torr, preferably, 0.5-7.0 Torr.

In one aspect of the invention, a CVD process for depositing a silicon oxide layer on a substrate comprises at least one cycle comprising the following steps: (i) introducing a silicon organic precursor into a deposition zone where a substrate is located; and (ii) introducing ozone into the deposition zone. In this aspect of the invention, the steps can be performed simultaneously or sequentially. The precursor and the ozone react to form a layer of silicon oxide on the substrate. Preferably, the deposition zone is maintained at a pressure ranging from 0.5 to 2.0 Torr and a temperature below 400° C.

This deposition process can be illustrated by the following equation:
Si precursor+O₃→SiO₂+byproducts (1)
For example, the deposition process can be illustrated by one or more of the following equations:
Si(NR¹R²)₄+O₃→SiO₂+byproducts (2)
Si(NR¹R²)_{4-w}L_{w}+O₃→SiO₂+byproducts (3)
where R¹ and R² are, independently, selected from hydrogen, C₁-C₆ alkyl, C₅-C₆ cyclic alkyls, halogen, and substituted alkyls and cyclic alkyls, where w equals 1, 2, 3 or 4, and where L is selected from hydrogen or halogen. Alternatively, the deposition process can be illustrated by one or more of the following equations:
Si₂(NR¹R²)₆+O₃→SiO₂+byproducts (4)
Si₂(NR¹R²)_{6-z}L_{z}+O₃→SiO₂+byproducts (5)
where R¹ and R² are, independently, selected from hydrogen, C₁-C₆ alkyl, C₅-C₆ cyclic alkyls, halogen, and substituted alkyls and cyclic alkyls, where z equals 1, 2, 3, 4, 5 or 6, and where L is selected from hydrogen or halogen.

In another aspect of the invention, a CVD process for depositing a silicon oxynitride layer on a substrate comprises at least one cycle comprising the following steps: (i) introducing a silicon organic precursor into a deposition zone where a substrate is located; (ii) introducing ozone into the deposition zone; and (iii) introducing a nitrogen source into the deposition zone. Once again, the steps can be performed simultaneously or sequentially. The precursor, ozone and nitrogen source react to form a layer of silicon oxynitride on the substrate. Preferably, the deposition zone is maintained at a pressure ranging from 0.5 to 2.0 Torr and a temperature below 400° C.

This deposition process can be illustrated by the following equation:
Si precursor+nitrogen source+O₃→SiOₓN_{y}+byproducts (6)
For example, the deposition process can be illustrated by one or more of the following equations:
Si(NR¹R²)₄+NH₃+O₃→SiOₓN_{y}+byproducts (7)
Si(NR¹R²)_{4-w}L_{w}+NH₃+O₃→SiOₓN_{y}+byproducts (8)
where R¹ and R² are, independently, selected from hydrogen, C₁-C₆ alkyl C₅-C₆ cyclic alkyls, halogen, and substituted alkyls and cyclic alkyls, where w equals 1, 2, 3 or 4, and where L is selected from hydrogen or halogen. Alternatively, the deposition process can be illustrated by one or more of the following equations:
Si₂(NR¹R²)₆+NH₃+O₃→SiOₓN_{y}+byproducts (9)
Si₂(NR¹R²)_{6-z}L_{z}+NH₃+O₃→SiOₓN_{y}+byproducts (10)
where R¹ and R² are, independently, selected from hydrogen, C₁-C₆ alkyl, C₅-C₆ cyclic alkyls, halogen, and substituted alkyls and cyclic alkyls, where z equals 1, 2, 3, 4, 5 or 6, and where L is selected from hydrogen or halogen. The ozone and nitrogen source gases may be introduced simultaneously or separately. Preferably, the ozone and nitrogen source gases are introduced as a mixture.

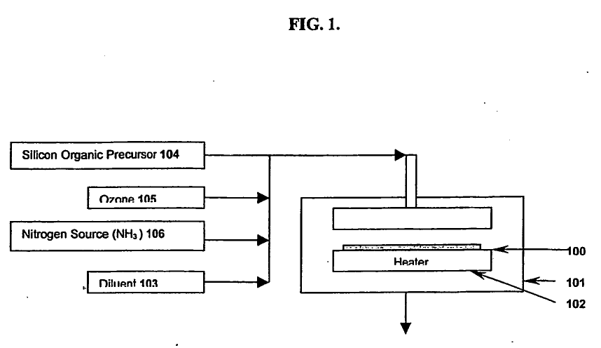

The aforementioned methods of depositing films in a low pressure low thermal CVD process are illustrated in FIG. 1. In FIG. 1, a silicon wafer 100 is loaded into the deposition chamber 101 with the transfer occurring near chamber base pressure. In the deposition chamber 101 the wafer 100 is heated to deposition temperature by a heater 102. In this example, process pressure is established by introducing an inert diluent gas flow 103 into the chamber 101. Then, the silicon organic precursor 104 and the ozone oxidizer 105 (and also NH₃ 106 if SiOₓN_{y} is to be deposited) gas flows are introduced into the chamber using conventional gas delivery methods used in the semiconductor and thin films industries. After an appropriate time required to achieve the target film thickness, the silicon precursor and oxidizer/NH₃ gas flows are turned off and the diluent inert gas flow is adjusted to purge the chamber of remaining reactants. After an appropriate purge time, the wafer is transferred out of the process chamber and back to the cassette.

In still another aspect of the invention, an ALD process for depositing a silicon oxide layer on a substrate comprises at least one cycle comprising the following the steps of: (i) introducing a silicon organic precursor into a deposition zone where a substrate is located; (ii) purging the deposition zone; and (iii) introducing ozone into the deposition zone to form a layer of silicon oxide on the substrate. In this aspect of the invention, the steps are performed sequentially. The cycle deposits one mono-layer of silicon oxide. The cycle can be repeated as many times as necessary to achieve the desired film thickness as long as each cycle is separated by an additional purging of the deposition zone. The overall equation for the process is the same as that show in Equations 1-5 above. However, the reaction is broken up into multiple steps separated by purges to insure mono-layer growth.

In yet another aspect of the invention, an ALD process for depositing a silicon oxynitride layer on a substrate comprises at least one cycle comprising the steps of: (i) introducing a silicon organic precursor into a deposition zone where a substrate is located; (ii) purging the deposition zone; and (iii) introducing ozone and a nitrogen source into the deposition zone. The steps are performed sequentially. The introduction of ozone and nitrogen can be done separately or simultaneously, in any order, optionally separated by a step of purging of the deposition chamber. The cycle deposits one mono-layer of silicon oxynitride. The cycle can repeated as many times as necessary to achieve the desired film thickness as long as each cycle is separated by an additional purging of the deposition zone. The overall equation for the process is the same as that show in Equations 6-10 above. However, the reaction is broken up into multiple steps separated by purges to insure mono-layer growth.

ALD has several advantages over traditional CVD. First, ALD can be performed at even lower temperatures. Second, ALD can produce ultra-thin conformal films. In fact, ALD can control film thickness on an atomic scale and be used to “nano-engineer” complex thin films. Third, ALD provides conformal coverage of thin films on non-planar substrates. However, process times for ALD are generally longer due to the increased number of pulses required per cycle.

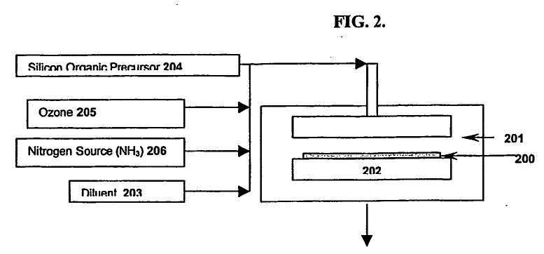

The aforementioned methods for depositing films by ALD are illustrated in the sequence of steps described in FIG. 2. In FIG. 2, after evacuating the chamber of gases, a wafer 200 is transferred into the deposition zone 201 and placed on the wafer heater 202 where the wafer is heated to deposition temperature. The deposition temperature can range from 100° C. to 550° C. but is preferably less than about 450° C. and more preferably in the range of 300° C. to 400° C. A steady flow of a diluent gas 203 is introduced into the deposition zone 201. This gas can be Ar, He, Ne, Ze, N₂ or other non-reactive gas. The pressure is established at the process pressure. The process pressure can be from 100 mTorr to 10 Torr, and preferably it is from 200 mTorr to 1.5 Torr. After steady state pressure has been achieved and after an appropriate time to remove any residual gases from the surface of the wafer 200, ALD deposition begins. First, a pulse of the silicon organic precursor vapor flow 204 is introduced into the deposition region by opening appropriate valves. The vapor flow rate can be from 1 to 1000 sccm, and is preferably in the range 5 to 100 sccm. The vapor may be diluted by a non-reactive gas such as Ar, N₂, He, Ne, or Xe. The dilution flow rate can be from 100 sccm to 1000 sccm. The precursor pulse time can be from 0.01 s to 10 s and is preferably in the range 0.05 to 2 s. At the end of the precursor pulse, the precursor vapor flow into the deposition zone 201 is terminated. The vapor delivery line to the deposition region is then purged for an appropriate time with a non-reacting gas 203. During the purge, a non-reactive gas 203 flows into the chamber through the vapor delivery line. The non-reactive gas can be Ar, He, Ne, Ze or N₂. The purge gas flow is preferably the same as the total gas flow through the line during the precursor pulse step. The vapor purge time can be from 0.1 s to 10 s but is preferably from 0.5 s to 5 s. At the end of the vapor purge step, a reactant gas flow is directed into the deposition zone 201 by activating appropriate valves (not shown). The reactant gas is ozone 205 for deposition SiO₂ and for the deposition of SiOₓN_{y} it is the combination of ozone 205 and ammonia 206. The total reactant gas flow can be from 100 to 2000 sccm and is preferably in the range 200 to 1000 sccm. The ozone concentration is in the range 150 to 300 g/m³ and is preferably around 200 g/m³. For deposition of SiOₓN_{y}, the ratio of oxidizer and ammonia flows can be from 0.2 to 10 depending on the desired composition and the temperature. The reactant pulse time can be from 0.1 s to 10 s but is preferably from 0.5 s to 3 s. After the reactant pulse is completed, the reactant delivery line to the deposition zone 201 is purged using a flow of non-reacting gas 203. The non-reacting gas can be He, Ne, Ar, Xe, or N₂. The purge flow is preferably the same as the total flow through the reactant delivery line during the reactant pulse. After the reactant pulse, the next precursor pulse occurs and the sequence is repeated as many times as necessary to achieve the desired film thickness.

The above sequence may be modified by inclusion of pumping during one or more of the purging steps in addition to the use of a purge gas. The above sequence can also be modified by the use of pumping during one or more of the purging steps instead of a purge gas.

The present methods can be utilized for both doped and undoped SiOx and SiOxNy formation. Typical applications of the present method in integrated circuit (IC) fabrication include, but are not limited to, pre-metal dielectrics (PMD), shallow trench isolation (STI), spacers, metal silicate gate dielectrics, and low-k dielectrics.

Having thus described the invention with the details and particularity required by the patent laws, what is claimed and desired protected by Letters Patent is set forth in the appended claims.

What is claimed:

1. A method for depositing silicon oxide on a substrate comprising the steps of introducing a silicon organic precursor and ozone into a deposition zone where a substrate is located.

2. The method of claim 1 where the deposition is performed by chemical vapor deposition and comprises at least one cycle comprising the following steps:
(i) introducing a silicon organic precursor into a deposition zone where a substrate is located; and
(ii) introducing ozone into the deposition zone.

3. The method of claim 2 where the steps are performed simultaneously.

4. The method of claim 2 where the steps are performed sequentially.

5. The method of claim 1 where the deposition is performed by atomic layer deposition and comprises at least one cycle comprising the following sequential steps:
(i) introducing a silicon organic precursor into a deposition zone where a substrate is located;
(ii) purging the deposition zone; and
(iii) introducing ozone into the deposition zone.

6. The method of claim 1 wherein the silicon organic precursor is selected from tetramethyldisiloxane (TMDSO), hexamethyldisiloxane (HMDSO), hexamethyldisilazane (HMDSN), and silicon tetrakis(ethylmethyamide) (TEMASi), alkylsilane, alkylaminosilane, alkylaminodisilane, alkyloxysilane, alkylsilanol, alkyloxysilanol.

7. The method of claim 1 wherein the silicon organic precursor has the formula Si(NR¹R²)_{4-w}L_{w} where R¹ and R² are, independently, selected from hydrogen, C₁-C₆ alkyl, C₅-C₆ cyclic alkyls, halogen, and substituted alkyls and cyclic alkyls, where w equals 1, 2, 3 or 4, and where L is selected from hydrogen or halogen.

8. The method of claim 1 wherein the silicon organic precursor has the formula Si₂(NR¹R²)_{6-z}L_{z}, where R¹ and R² are, independently, selected from hydrogen, C₁-C₆ alkyl, C₅-C₆ cyclic alkyls, halogen, and substituted alkyls and cyclic alkyls, where z equals 1, 2, 3, 4, 5 or 6, and where L is selected from hydrogen or halogen.

9. The method of claim 1 wherein the deposition zone is maintained at a pressure ranging from 1 mTorr to 760 Torr.

10. The method of claim 1 wherein the deposition is performed at a temperature between 200° C. to 400° C.

11. The method of claim 1 wherein the ozone is introduced into the deposition zone provides an ozone concentration in the range 10 to 400 g/m³.

12. The method of claim 1 where the substrate is a silicon substrate, ceramics, metals, plastics, glass, and organic polymers.

13. A method for depositing silicon oxynitride on a substrate comprising the steps of introducing a silicon organic precursor, ozone, and a nitrogen source into a deposition zone where a substrate is located.

14. The method of claim 13 where the deposition is performed by chemical vapor deposition and comprises at least one cycle comprising the following steps:
(i) introducing a silicon organic precursor into a deposition zone where a substrate is located;
(ii) introducing ozone into the deposition zone; and
(iii) introducing a nitrogen source into the deposition zone.

15. The method of claim 14 where the steps are performed simultaneously.

16. The method of claim 14 where the steps are performed sequentially.

17. The method of claim 13 where the deposition is performed by atomic layer deposition and comprises at least one cycle comprising the following sequential steps:
(i) introducing a silicon organic precursor into a deposition zone where a substrate is located;
(ii) purging the deposition zone; and
(iii) introducing ozone and a nitrogen source into the deposition zone.

18. The method of claim 17 where the ozone and nitrogen source are introduced separately in any order.

19. The method of claim 17 where the ozone and nitrogen source are introduced simultaneously.

20. The method of claim 13 wherein the silicon organic precursor is selected from tetramethyldisiloxane (TMDSO), hexamethyldisiloxane (HMDSO), hexamethyldisilazane (HMDSN), and silicon tetrakis(ethyhnethyamide) (TEMASi), alkylsilane, alkylaminosilane, allylaminodisilane, alkyloxysilane, alkylsilanol, alkyloxysilanol.

21. The method of claim 13 wherein the silicon organic precursor has the formula Si(NR¹R²)_{4-w}L_{w} where R¹ and R² are, independently, selected from hydrogen, C₁-C₆ alkyl, C₅-C₆ cyclic alkyls, halogen, and substituted alkyls and cyclic alkyls, where w equals 1, 2, 3 or 4, and where L is selected from hydrogen or halogen.

22. The method of claim 13 wherein the silicon organic precursor has the formula Si₂(NR¹R²)_{6-z}L_{z}, where R¹ and R² are, independently, selected from hydrogen, C₁-C₆ alkyl, C₅-C₆ cyclic alkyls, halogen, and substituted alkyls and cyclic alkyls, where z equals 1, 2, 3, 4, 5 or 6, and where L is selected from hydrogen or halogen.

23. The method of claim 13 where the nitrogen source is selected from atomic nitrogen, nitrogen gas, ammonia, hydrazine, alkylhydrazine, and alkylamine.

24. The method of claim 13 wherein the deposition zone is maintained at a pressure ranging from 1 mTorr to 760 Torr.

25. The method of claim 13 wherein the deposition is performed at a temperature below 400° C.

26. The method of claim 13 wherein the ozone introduced into the deposition zone provides an ozone concentration ranging from 10 to 400 g/m³.

27. The method of claim 13 where the substrate is a silicon substrate, ceramics, metals, plastics, glass, and organic polymers.
